(19) United States
(12) Patent Application Publication
(10) Pub. No.: US 2026/0020438 A1
(43) Pub. Date: Jan. 15, 2026

(54) DISPLAY APPARATUS, METHOD OF MANUFACTURING DISPLAY APPARATUS, AND ELECTRONIC DEVICE INCLUDING DISPLAY APPARATUS

(71) Applicant: Samsung Display Co., Ltd., Yongin-Si (KR)

(72) Inventors: Keunwoo Kim, Yongin-si (KR); Soyoung Koo, Yongin-si (KR); Hyoungdo Kim, Yongin-si (KR); Hyungjun Kim, Yongin-si (KR); Geunchul Park, Yongin-si (KR)

(21) Appl. No.: 19/095,385

(22) Filed: Mar. 31, 2025

(30) Foreign Application Priority Data
Jul. 12, 2024 (KR) 10-2024-0092583

(51) Int. Cl. H10K 59/121; H10K 59/12

(52) U.S. Cl. CPC H10K 59/1213; H10K 59/1201

(57) ABSTRACT

A display apparatus includes a substrate, a first transistor disposed on the substrate and including a first active pattern including a polysilicon semiconductor, and a second transistor disposed on the substrate and including a second active pattern and a lower gate electrode insulated from the second active pattern and disposed below the second active pattern, the second active pattern including an oxide semiconductor, wherein the lower gate electrode of the second transistor is formed of a same material and formed on a same plane as the first active pattern of the first transistor.

### CROSS-REFERENCE TO RELATED APPLICATION

This application is based on and claims priority under 35 U.S.C. § 119 to Korean Patent Application No. 10-2024-0092583, filed on Jul. 12, 2024, in the Korean Intellectual Property Office, the disclosure of which is incorporated by reference herein in its entirety.

### BACKGROUND

### 1. Field

One or more embodiments relate to a display apparatus and a method of manufacturing the display apparatus, and more particularly, to a display apparatus including a light-emitting diode. One or more embodiments relate to an electronic device including a display apparatus.

### 2. Description of the Related Art

A display apparatus visually displays images. The display apparatus may provide images by using light-emitting diodes. As the use of display apparatuses has diversified, various designs have been attempted to improve the quality of the display apparatuses.

### SUMMARY

One or more embodiments include a display apparatus driven by a transistor including a silicon semiconductor and a transistor including an oxide transistor. One or more embodiments include a method of manufacturing a display apparatus in which the number of masks used in a manufacturing process may be reduced. However, these objectives are examples, and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a substrate, a first transistor disposed on the substrate and including a first active pattern including a polysilicon semiconductor, and a second transistor disposed on the substrate and including a second active pattern and a lower gate electrode insulated from the second active pattern and disposed below the second active pattern, the second active pattern including an oxide semiconductor, wherein the lower gate electrode of the second transistor comprises a same material and is disposed on a same plane as the first active pattern of the first transistor.

In an embodiment, the lower gate electrode and the first active pattern may be connected to each other to form a single body.

In an embodiment, the lower gate electrode may include a doped polysilicon semiconductor.

In an embodiment, the display apparatus may further include a first capacitor including a first-1 electrode and a first-2 electrode, wherein the first-1 electrode may comprise the same material and be disposed on the same plane as the first active pattern.

In an embodiment, the second transistor may further include an upper gate electrode insulated from the second active pattern and disposed on the second active pattern, and the upper gate electrode of the second transistor and the first-2 electrode of the first capacitor may comprise a same material and be disposed on a same plane.

In an embodiment, the display apparatus may further include a second capacitor including a second-1 electrode and a second-2 electrode, wherein the second-1 electrode may comprise the same material and be disposed on the same plane as the first active pattern, and the second-2 electrode may comprise a same material and be disposed on a same plane as the second active pattern.

In an embodiment, each of the first-1 electrode and the second-1 electrode may include a doped polysilicon semiconductor.

In an embodiment, the second-2 electrode may include a doped oxide semiconductor.

In an embodiment, the second-2 electrode and the second active pattern may be connected to each other to form a single body.

In an embodiment, the first active pattern, the lower gate electrode, the first-1 electrode, and the second-1 electrode may be integral.

According to one or more embodiments, a method of manufacturing a display apparatus includes forming a first semiconductor pattern including a polysilicon semiconductor on a substrate, forming a lower gate electrode by doping a first portion of the first semiconductor pattern, and disposing a second semiconductor pattern including an oxide semiconductor on the lower gate electrode to be insulated from the lower gate electrode.

In an embodiment, a first-1 electrode of a first capacitor a second-1 electrode of a second capacitor are formed at the same time when doping the first portion of the first semiconductor pattern by doping a second portion of the first semiconductor pattern and a third portion of the first semiconductor pattern, respectively.

In an embodiment, the forming of the lower gate electrode, the forming of the first-1 electrode, and the forming of the second-1 electrode may be substantially performed simultaneously.

In an embodiment, the method may further include forming a first gate electrode on a fourth portion of the first semiconductor pattern, and doping the first semiconductor pattern including the first portion, the second portion, the third portion, and the fourth portion.

In an embodiment, the method may further include forming a first source electrode and a first drain electrode on the first semiconductor pattern to be connected to the fourth portion of the first semiconductor pattern.

In an embodiment, the method may further include forming a first-2 electrode insulated from the first-1 electrode on the first-1 electrode of the first capacitor, and an upper gate electrode on the second semiconductor pattern to be insulated from the second semiconductor pattern, wherein the forming of the upper gate electrode and the forming of the first-2 electrode may be substantially performed simultaneously.

In an embodiment, the method may further include forming a second-2 electrode of the second capacitor by doping a first portion of the second semiconductor pattern.

In an embodiment, the disposing of the upper gate electrode may include forming the upper gate electrode on a second portion of the second semiconductor pattern, and the forming of the second-2 electrode may include doping the second semiconductor pattern including the first portion and the second portion.

In an embodiment, the method may further include forming a second source electrode and a second drain electrode on the second semiconductor pattern to be connected to the second portion of the second semiconductor pattern.

According to one or more embodiments, an electronic device includes a display apparatus, wherein the display apparatus includes a substrate, a first transistor disposed on the substrate and comprising a first active pattern comprising a polysilicon semiconductor, and a second transistor disposed on the substrate and comprising a second active pattern and a lower gate electrode insulated from the second active pattern and disposed below the second active pattern, the second active pattern comprising an oxide semiconductor, wherein the lower gate electrode of the second transistor comprises a same material and is formed on a same plane as the first active pattern of the first transistor.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to an embodiment;

FIG. 2 is an equivalent circuit diagram illustrating a sub-pixel circuit configured to drive a sub-pixel and a light-emitting diode connected to the sub-pixel circuit according to an embodiment;

FIG. 3 is a cross-sectional view of a portion of a display apparatus according to an embodiment;

FIGS. 4A and 4B are schematic plan views each illustrating a portion of a display apparatus according to an embodiment;

FIGS. 5A, 5B, 5C, 5D, 5E, 5F, 5G, 5H, 5I, 5J, 5K, 5L, 5M, 5N, 5O, 5P and 5Q are cross-sectional views of a method of manufacturing a display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

Like reference numerals in the drawings denote like elements, and thus their description will not be repeated.

In the following embodiments, while such terms as “first,” “second,” etc., may be used to describe various elements, such elements must not be limited to the above terms.

In the following embodiments, an expression used in the singular encompasses the expression of the plural, unless it has a clearly different meaning in the context.

In the following embodiments, it is to be understood that the terms such as “including” and “having” are intended to indicate the existence of the features, or elements disclosed in the disclosure, and are not intended to preclude the possibility that one or more other features or elements may exist or may be added.

It will be understood that when a layer, region, or element is referred to as being formed on another layer, region, or element, it can be directly or indirectly formed on the other layer, region, or element. That is, for example, intervening layers, regions, or elements may be present.

Sizes of elements in the drawings may be exaggerated for convenience of explanation. In other words, since sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the disclosure, “A and/or B” may include “A,” “B,” or “A and B.” In addition, “at least one of A and B” may include “A,” “B,” or “A and B.”

It will be understood that when a layer, region, or component is referred to as being connected to another layer, region, or component, it can be directly or indirectly connected to the other layer, region, or component. That is, for example, intervening layers, regions, or components may be present. For example, it will be understood that when a layer, region, or component is referred to as being electrically connected to another layer, region, or component, it can be directly or indirectly electrically connected to the other layer, region, or component. That is, for example, intervening layers, regions, or components may be present.

The x-direction, the y-direction, and the z-direction are not limited to three axes of the rectangular coordinate system, and may be interpreted in a broader sense. For example, the x direction, the y direction, and the z direction may be perpendicular to one another, or may represent different directions that are not perpendicular to one another.

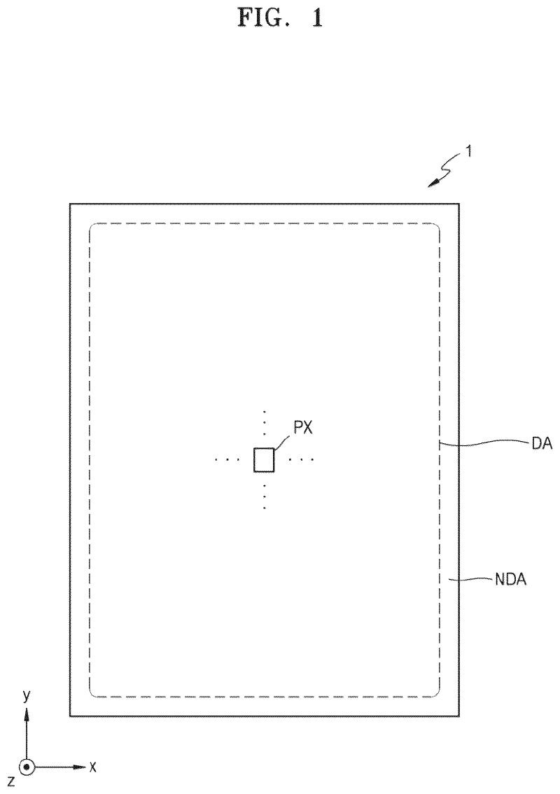

FIG. 1 is a schematic plan view of a display apparatus according to an embodiment.

Referring to FIG. 1, a display apparatus 1 may include a display area DA and a non-display area NDA outside the display area DA. The display area DA may display an image through sub-pixels PX arranged in the display area DA. The non-display area NDA is an area which is arranged outside the display area DA and does not display an image, and may entirely surround the display area DA. A driver or the like configured to provide electrical signals or power to the display area DA may be arranged in the non-display area NDA. Pads, which are areas to which an electronic device or a printed circuit board may be electrically connected, may be arranged in the non-display area NDA.

FIG. 1 shows that the display area DA has a rectangular shape in which a length of the display area DA in an x direction is less than a length of the display area DA in a y direction, but in an embodiment, the display area DA may have a rectangular shape in which the length of the display area DA in the y direction is less than the length of the display area DA in the x direction. FIG. 1 shows that the display area DA has an approximately rectangular shape, but in an embodiment, the display area DA may have various shapes, such as an N-gonal shape (where N is a natural number of 3 or more, N≠4), a circular shape, an oval shape, or the like. FIG. 1 shows that a corner of the display area DA has a shape including a vertex where straight lines meet, but in an embodiment, the display area DA may have a polygonal shape with rounded corner portions.

Hereinafter, for convenience of explanation, a case where the display apparatus 1 is an electronic device that is a smartphone is described, but the display apparatus 1 of the disclosure is not limited thereto. The display apparatus 1 may be a portable electronic device such as a mobile phone, a smartphone, a tablet personal computer (PC), a mobile communication terminal, an electronic notebook, an electronic book, a portable multimedia player (PMP), a navigation device, an Ultra Mobile PC (UMPC), or the like, and may also be used in various products such as a television, a laptop computer, a monitor, an advertisement board, an Internet of things (IoT) device, or the like. In addition, the display apparatus 1 according to an embodiment may be used as a wearable device such as a smart watch, a watch phone, a glasses-type display, and a head-mounted display (HMD). In addition, the display apparatus 1 according to an embodiment may also be applied to a dashboard of a vehicle, a center fascia of a vehicle or a center information display (CID) disposed on a dashboard, a mirror display replacing a side mirror of a vehicle, and a display screen disposed on a rear surface of a front seat as entertainment for a passenger in a back seat of a vehicle.

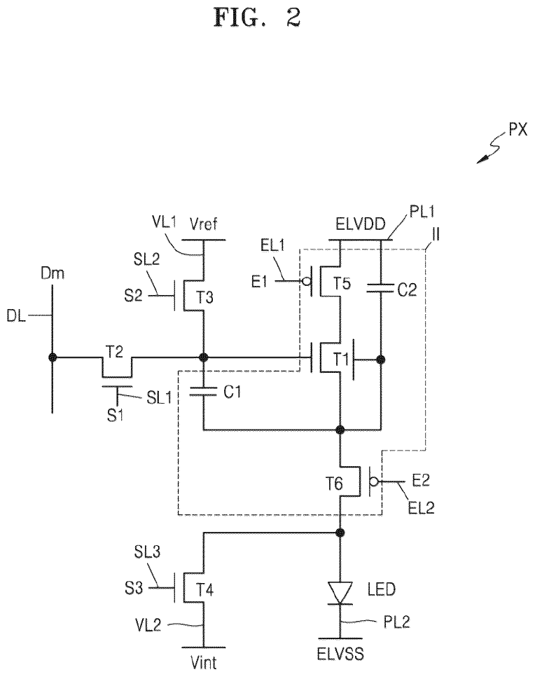

FIG. 2 is an equivalent circuit diagram illustrating a sub-pixel circuit driving the sub-pixel PX and a light-emitting diode LED connected to the sub-pixel circuit as a display element according to an embodiment.

Referring to FIG. 2, the sub-pixel circuit may include first to sixth transistors T1, T2, T3, T4, T5, and T6, a first capacitor C1, and a second capacitor C2. The sub-pixel circuit may be connected to a plurality of signal lines, a first voltage line VL1, a second voltage line VL2, and a first power line PL1. The plurality of signal lines may include a data line DL, a first scan line SL1, a second scan line SL2, a third scan line SL3, a first emission control line EL1, and a second emission control line EL2.

The first power line PL1 may be configured to transmit a first power voltage ELVDD to the sub-pixel circuit. The first voltage line VL1 may be configured to transmit a first voltage Vref to the sub-pixel circuit. The second voltage line VL2 may be configured to transmit a second voltage Vint to the sub-pixel circuit. The data line DL may be configured to transmit a data signal Dm to the sub-pixel circuit. The first scan line SL1 may be configured to transmit a first scan signal S1 to the sub-pixel circuit. The second scan line SL2 may be configured to transmit a second scan signal S2 to the sub-pixel circuit. The third scan line SL3 may be configured to transmit a third scan signal S3 to the sub-pixel circuit. The first emission control line EL1 may be configured to transmit a first emission control signal E1 to the sub-pixel circuit. The second emission control line EL2 may be configured to transmit a second emission control signal E2 to the sub-pixel circuit.

The first transistor T1 may be connected to the first power line PL1 via the fifth transistor T5. The first transistor T1 may be connected to the light-emitting diode LED via the sixth transistor T6. A gate of the first transistor T1 may be connected to the second transistor T2, the third transistor T3, and the first capacitor C1.

The second transistor T2 may be connected to the data line DL. The second transistor T2 may be connected to the gate of the first transistor T1, the third transistor T3, and the first capacitor C1. A gate of the second transistor T2 may be connected to the first scan line SL1.

The third transistor T3 may be connected to the first voltage line VL1. The third transistor T3 may be connected to the gate of the first transistor T1, the second transistor T2, and the first capacitor C1. A gate of the third transistor T3 may be connected to the second scan line SL2.

The fourth transistor T4 may be connected to the second voltage line VL2. The fourth transistor T4 may be connected to the sixth transistor T6 and the light-emitting diode LED. A gate of the fourth transistor T4 may be connected to the third scan line SL3.

The fifth transistor T5 may be connected to the first power line PL1. The fifth transistor T5 may be connected to the first transistor T1. A gate of the fifth transistor T5 may be connected to the first emission control line EL1.

The sixth transistor T6 may be connected to the light-emitting diode LED. The sixth transistor T6 may be connected to the first transistor T1. A gate of the sixth transistor T6 may be connected to the second emission control line EL2.

The first capacitor C1 may be connected to the gate of the first transistor T1 and the sixth transistor T6. The second capacitor C2 may be connected to the first power line PL1 and the first transistor T1.

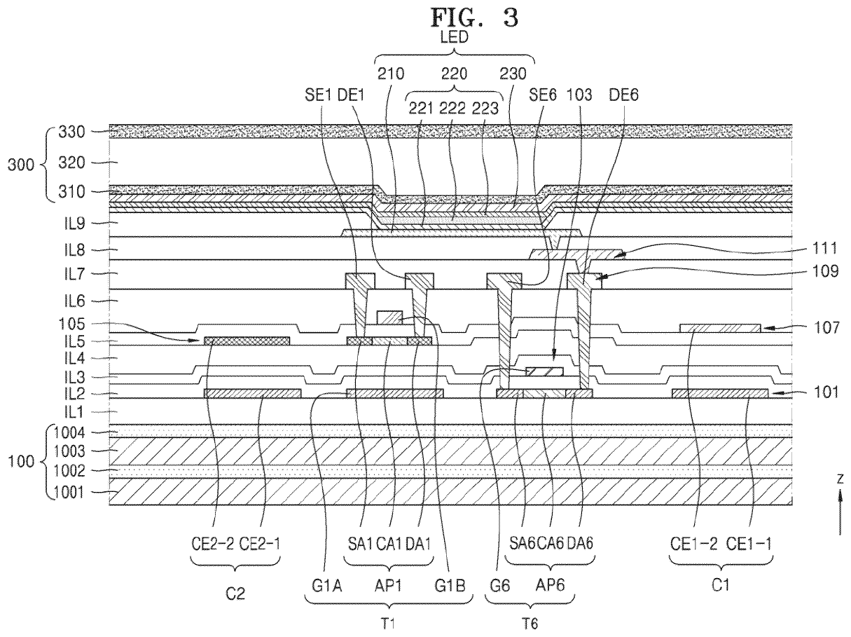

The light-emitting diode LED may be connected to the sixth transistor T6 and a second power line PL2. A sub-pixel electrode 210 (refer to FIG. 3) of the light-emitting diode LED may be connected to the sixth transistor T6. An opposite electrode 230 (refer to FIG. 3) of the light-emitting diode LED may be connected to the second power line PL2. The light-emitting diode LED may receive the first power voltage ELVDD through the first power line PL1, the fifth transistor T5, the first transistor T1, and the sixth transistor T6. The light-emitting diode LED may receive a second power voltage ELVSS through the second power line PL2. The light-emitting diode LED may display an image by emitting light when a current flows through the light-emitting diode LED which is caused by a potential difference between the first power voltage ELVDD and the second power voltage ELVSS.

In an embodiment, at least one of the first transistor T1, the second transistor T2, the third transistor T3, and the fourth transistor T4 may include an oxide semiconductor. For example, at least one of the first transistor T1, the second transistor T2, the third transistor T3, and the fourth transistor T4 may include indium gallium zinc oxide (IGZO). In an embodiment, at least one of the first transistor T1, the second transistor T2, the third transistor T3, and the fourth transistor T4 may be an N-channel transistor. In an embodiment, at least one of the fifth transistor T5 and the sixth transistor T6 may include a polysilicon semiconductor. For example, at least one of the fifth transistor T5 and the sixth transistor T6 may include a semiconductor layer having low-temperature polycrystalline silicon LTPS. In an embodiment, at least one of the fifth transistor T5 and the sixth transistor T6 may be a P-channel transistor.

FIG. 3 is a cross-sectional view of a portion of a display apparatus according to an embodiment. For example, FIG. 3 is a cross-sectional view of a portion of the sub-pixel PX (refer to FIG. 1) of the display apparatus.

Referring to FIG. 3, the first transistor T1, the sixth transistor T6, the first capacitor C1, and the second capacitor C2 may be disposed on a substrate 100. The second to fifth transistors T2, T3, T4, and T5 (refer to FIG. 2) described above with reference to FIG. 2 may also be disposed on the substrate 100, but are omitted for convenience of illustration and explanation.

In an embodiment, the substrate 100 may be a flexible substrate. For example, the substrate 100 may include a first substrate layer 1001, a second substrate layer 1002, a third substrate layer 1003, and a fourth substrate layer 1004. The second substrate layer 1002 may be disposed on the first substrate layer 1001. The third substrate layer 1003 may be disposed on the second substrate layer 1002. The fourth substrate layer 1004 may be disposed on the third substrate layer 1003. At least one of the first substrate layer 1001 and the third substrate layer 1003 may include a polymer. For example, at least one of the first substrate layer 1001 and the third substrate layer 1003 may include polyimide (PI). At least one of the second substrate layer 1002 and the fourth substrate layer 1004 may include an inorganic insulating material. For example, at least one of the second substrate layer 1002 and the fourth substrate layer 1004 may include one or more selected from among silicon oxide (SiO₂), silicon nitride (SiNₓ), and silicon oxynitride (SiON). In another embodiment, the substrate 100 may also be a rigid substrate (e.g., a glass substrate).

A first insulating layer IL1 may be disposed on the substrate 100. The first insulating layer IL1 may include an inorganic insulating material. For example, the first insulating layer IL1 may include one or more selected from among silicon oxide (SiO₂), silicon nitride (SiNₓ), and silicon oxynitride (SiON). The first insulating layer IL1 may have a single layer or multiple layers. In an embodiment, the first insulating layer IL1 may be a buffer layer.

A first layer 101 may be disposed on the first insulating layer IL1. The first layer 101 may include a polysilicon semiconductor. For example, the first layer 101 may include LTPS. A portion of the first layer 101 may include a doped (e.g., P-doped) semiconductor and the doped semiconductor may be conductive. Another portion of the first layer 101 may include an undoped semiconductor. In an embodiment, the first layer 101 may be a first semiconductor pattern.

The first transistor T1 may include a first active pattern AP1, a first lower gate electrode GIA, and a first upper gate electrode G1B. The first active pattern AP1 may be disposed on a fourth insulating layer IL4 to be described below. The first upper gate electrode GIB may be disposed on a fifth insulating layer IL5 to be described below. The first lower gate electrode GIA may be disposed on the first insulating layer IL1. The first lower gate electrode GIA may be arranged in the first layer 101. The first lower gate electrode GIA may be the doped (e.g., P-doped) portion of the first layer 101. Accordingly, the first lower gate electrode GIA may include a doped polysilicon semiconductor and may be conductive.

The sixth transistor T6 may include a sixth active pattern AP6 and a sixth gate electrode G6. The sixth gate electrode G6 may be disposed on a second insulating layer IL2 to be described below. The sixth active pattern AP6 may be disposed on the first insulating layer IL1. The sixth active pattern AP6 may be arranged in the first layer 101. A portion of the sixth active pattern AP6 may be the doped portion of the first layer 101, and another portion of the sixth active pattern AP6 may be the undoped portion of the first layer 101.

For example, the sixth active pattern AP6 may include a sixth source area SA6, a sixth channel area CA6, and a sixth drain area DA6. The sixth channel area CA6 may be arranged between the sixth source area SA6 and the sixth drain area DA6. The sixth source area SA6 and the sixth drain area DA6 may be the doped (e.g., P-doped) portion of the first layer 101. Accordingly, the sixth source area SA6 and the sixth drain area DA6 may each include a doped polysilicon semiconductor and may be conductive. The sixth channel area CA6 may be the undoped portion of the first layer 101. Accordingly, the sixth channel area CA6 may include an undoped polysilicon semiconductor.

The first capacitor C1 may include a first-1 electrode CE1-1 and a first-2 electrode CE1-2. The first-1 electrode CE1-1 may be disposed on the first insulating layer IL1. The first-1 electrode CE1-1 may be arranged in the first layer 101. The first-1 electrode CE1-1 may be the doped (e.g., P-doped) portion of the first layer 101. Accordingly, the first-1 electrode CE1-1 may include a doped polysilicon semiconductor and may be conductive. The first-2 electrode CE1-2 may be disposed on the fifth insulating layer IL5 to be described below.

The second capacitor C2 may include a second-1 electrode CE2-1 and a second-2 electrode CE2-2. The second-1 electrode CE2-1 may be disposed on the first insulating layer IL1. The second-1 electrode CE2-1 may be arranged in the first layer 101. The second-1 electrode CE2-1 may be the doped (e.g., P-doped) portion of the first layer 101. Accordingly, the second-1 electrode CE2-1 may include a doped polysilicon semiconductor and may be conductive. The second-2 electrode CE2-2 may be disposed on the fourth insulating layer IL4 to be described below.

In other words, the first lower gate electrode GIA, the sixth active pattern AP6, the first-1 electrode CE1-1, and the second-1 electrode CE2-1 may be disposed on the same layer (e.g., on the first insulating layer IL1). Alternatively, the first lower gate electrode GIA, the sixth active pattern AP6, the first-1 electrode CE1-1, and the second-1 electrode CE2-1 may be disposed on the same layer (e.g., the first layer 101). In an embodiment, at least some of the first lower gate electrode GIA, the sixth active pattern AP6, the first-1 electrode CE1-1, and the second-1 electrode CE2-1 may be formed substantially at the same time. In an embodiment, the first lower gate electrode G1A, the sixth active pattern AP6, the first-1 electrode CE1-1, and the second-1 electrode CE2-1 may be connected to each other to form a single body.

The second insulating layer IL2 may be disposed on the first layer 101. The second insulating layer IL2 may entirely cover the first layer 101. Hereinafter, “entirely cover” may mean that one layer covers a layer disposed below the one layer except regions corresponding to contact regions. The second insulating layer IL2 may include an inorganic insulating material. For example, the second insulating layer IL2 may include one or more selected from among silicon oxide (SiO₂), silicon nitride (SiNₓ), and silicon oxynitride (SiON). The second insulating layer IL2 may have a single layer or multiple layers. In an embodiment, the second insulating layer IL2 may include silicon oxide (SiO₂). In an embodiment, the second insulating layer IL2 may be a first gate insulating layer.

The sixth gate electrode G6 of the sixth transistor T6 may be disposed on the second insulating layer IL2. The sixth gate electrode G6 may be disposed in a second layer 103. The sixth gate electrode G6 may overlap the sixth channel area CA6 of the sixth active pattern AP6. The second layer 103 may be a conductive layer including metal. Accordingly, the sixth gate electrode G6 may include the metal and may be conductive. For example, the sixth gate electrode G6 may include one or more selected from among aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu). The sixth gate electrode G6 may have a single layer or multiple layers. In an embodiment, the sixth gate electrode G6 may include Mo.

A third insulating layer IL3 may be disposed on the second layer 103. The third insulating layer IL3 may entirely cover the second layer 103. The third insulating layer IL3 may include an inorganic insulating material. For example, the third insulating layer IL3 may include one or more selected from among silicon oxide (SiO₂), silicon nitride (SiNₓ), and silicon oxynitride (SiON). The third insulating layer IL3 may have a single layer or multiple layers. In an embodiment, the third insulating layer IL3 may include silicon nitride (SiNₓ). In an embodiment, the third insulating layer IL3 may be a portion of a first interlayer insulating layer.

The fourth insulating layer IL4 may be disposed on the third insulating layer IL3. The fourth insulating layer IL4 may entirely cover the third insulating layer IL3. The fourth insulating layer IL4 may include an inorganic insulating material. For example, the fourth insulating layer IL4 may include one or more selected from among silicon oxide (SiO₂), silicon nitride (SiNₓ), and silicon oxynitride (SiON). The fourth insulating layer IL4 may have a single layer or multiple layers. In an embodiment, the fourth insulating layer IL4 may include silicon oxide (SiO₂). In an embodiment, the fourth insulating layer IL4 may be a portion of the first interlayer insulating layer.

A third layer 105 may be disposed on the fourth insulating layer IL4. The third layer 105 may include an oxide semiconductor. For example, the third layer 105 may include IGZO. A portion of the third layer 105 may include a doped (e.g., N-doped) semiconductor and may be conductive. Another portion of the third layer 105 may include an undoped semiconductor. In an embodiment, the third layer 105 may be a second semiconductor pattern.

The first active pattern AP1 of the first transistor T1 and the second-2 electrode CE2-2 of the second capacitor C2 may be disposed on the fourth insulating layer IL4. The first active pattern AP1 of the first transistor T1 and the second-2 electrode CE2-2 of the second capacitor C2 may be disposed in the third layer 105. A portion of the first active pattern AP1 may be the doped (e.g., N-doped) portion of the third layer 105, and another portion of the first active pattern AP1 may be the undoped portion of the third layer 105.

For example, the first active pattern AP1 may include a first source area SA1, a first channel area CA1, and a first drain area DA1. The first channel area CA1 may be arranged between the first source area SA1 and the first drain area DA1. The first source area SA1 and the first drain area DA1 may be the doped (e.g., N-doped) portion of the third layer 105. Accordingly, the first source area SA1 and the first drain area DA1 may each include a doped oxide semiconductor and may be conductive. The first channel area CA1 may be the undoped portion of the third layer 105. Accordingly, the first channel area CA1 may include an undoped oxide semiconductor.

The second-2 electrode CE2-2 of the second capacitor C2 may be the doped (e.g., N-doped) portion of the third layer 105. Accordingly, the second-2 electrode CE2-2 may include a doped oxide semiconductor and may be conductive.

In other words, the first active pattern AP1 and the second-2 electrode CE2-2 may be disposed on the same layer (e.g., on the fourth insulating layer IL4). Alternatively, the first active pattern AP1 and the second-2 electrode CE2-2 may be disposed on the same layer (e.g., the third layer 105). In an embodiment, at least a portion of the first active pattern AP1 and the second-2 electrode CE2-2 may be formed substantially at the same time. In an embodiment, the first active pattern AP1 and the second-2 electrode CE2-2 may be connected to each other to form a single body.

The fifth insulating layer IL5 may be disposed on the third layer 105. The fifth insulating layer IL5 may entirely cover the third layer 105. The fifth insulating layer IL5 may include an inorganic insulating material. For example, the fifth insulating layer IL5 may include one or more selected from among silicon oxide (SiO₂), silicon nitride (SiNₓ), and silicon oxynitride (SiON). The fifth insulating layer IL5 may have a single layer or multiple layers. In an embodiment, the fifth insulating layer IL5 may include silicon oxide (SiO₂). In an embodiment, the fifth insulating layer IL5 may be a second gate insulating layer.

A fourth layer 107 may be disposed on the fifth insulating layer IL5. The fourth layer 107 may be a conductive layer including metal. For example, the fourth layer 107 may include one or more selected from among Al, Pt, Pd, Ag, Mg, Au, Ni, Nd, Ir, Cr, Ca, Mo, Ti, W, and Cu. The fourth layer 107 may have a single layer or multiple layers. In an embodiment, the fourth layer 107 may include Mo and Ti. In an embodiment, the fourth layer 107 may include a multi-layered structure in which Mo is disposed on Ti.

The first upper gate electrode GIB of the first transistor T1 may be disposed on the fifth insulating layer IL5. The first upper gate electrode GIB may be disposed in the fourth layer 107. The first upper gate electrode GIB may overlap the first channel area CA1 of the first active pattern AP1. The first upper gate electrode G1B may include metal and may be conductive, similar to the fourth layer 107.

The first-2 electrode CE1-2 of the first capacitor C1 may be disposed on the fifth insulating layer IL5. The first-2 electrode CE1-2 may be disposed in the fourth layer 107. The first-2 electrode CE1-2 may include metal and may be conductive, similar to the fourth layer 107.

In an embodiment, the first upper gate electrode G1B and the first-2 electrode CE1-2 may be formed substantially at the same time. In an embodiment, the first upper gate electrode G1B and the first-2 electrode CE1-2 may be connected to each other to form a single body.

A sixth insulating layer IL6 may be disposed on the fourth layer 107. The sixth insulating layer IL6 may entirely cover the fourth layer 107. The sixth insulating layer IL6 may include an inorganic insulating material. For example, the sixth insulating layer IL6 may include one or more selected from among silicon oxide (SiO₂), silicon nitride (SiNₓ), and silicon oxynitride (SiON). The sixth insulating layer IL6 may have a single layer or multiple layers. In an embodiment, the sixth insulating layer IL6 may include silicon oxide (SiO₂) and silicon nitride (SiNₓ). In an embodiment, the sixth insulating layer IL6 may include a multi-layered structure in which silicon nitride (SiNₓ) is disposed on silicon oxide (SiO₂). In an embodiment, the sixth insulating layer IL6 may be a second interlayer insulating layer.

A fifth layer 109 may be disposed on the sixth insulating layer IL6. The fifth layer 109 may be a conductive layer including metal. For example, the fifth layer 109 may include one or more selected from among Al, Pt, Pd, Ag, Mg, Au, Ni, Nd, Ir, Cr, Ca, Mo, Ti, W, and Cu. The fifth layer 109 may have a single layer or multiple layers. In an embodiment, the fifth layer 109 may include Al and Ti. In an embodiment, the fifth layer 109 may include a multi-layered structure in which Ti, Al, and Ti are sequentially arranged.

A first source electrode SE1, a first drain electrode DE1, a sixth source electrode SE6, and a sixth drain electrode DE6 may be disposed on the sixth insulating layer IL6. The first source electrode SE1, the first drain electrode DE1, the sixth source electrode SE6, and the sixth drain electrode DE6 may be disposed in the fifth layer 109. Each of the first source electrode SE1, the first drain electrode DE1, the sixth source electrode SE6, and the sixth drain electrode DE6 may include metal and may be conductive, similar to the fifth layer 109.

The first source electrode SE1 may overlap the first source area SA1 of the first active pattern AP1. The first source electrode SE1 may be connected to the first source area SA1 through a contact hole formed in the sixth insulating layer IL6 and the fifth insulating layer IL5. The first drain electrode DE1 may overlap the first drain area DA1 of the first active pattern AP1. The first drain electrode DE1 may be connected to the first drain area DA1 through a contact hole formed in the sixth insulating layer IL6 and the fifth insulating layer IL5. The sixth source electrode SE6 may overlap the sixth source area SA6 of the sixth active pattern AP6. The sixth source electrode SE6 may be connected to the sixth source area SA6 through a contact hole formed in the sixth insulating layer IL6, the fifth insulating layer IL5, the fourth insulating layer IL4, the third insulating layer IL3, and the second insulating layer IL2. The sixth drain electrode DE6 may overlap the sixth drain area DA6 of the sixth active pattern AP6. The sixth drain electrode DE6 may be connected to the sixth drain area DA6 through a contact hole formed in the sixth insulating layer IL6, the fifth insulating layer IL5, the fourth insulating layer IL4, the third insulating layer IL3, and the second insulating layer IL2.

A seventh insulating layer IL7 may be disposed on the fifth layer 109. The seventh insulating layer IL7 may entirely cover the fifth layer 109. The seventh insulating layer IL7 may include an organic insulating material. For example, the seventh insulating layer IL7 may include at least one selected from among benzocyclobutene, PI, hexamethyldisiloxane, a general commercial polymer such as polymethylmethacrylate or polystyrene, a polymer derivative having a phenol group, an acrylic polymer, an imide polymer, an aryl ether polymer, an amide polymer, a fluorine polymer, a p-xylene polymer, a vinyl alcohol polymer, or the like. The seventh insulating layer IL7 may have a single layer or multiple layers. In an embodiment, the seventh insulating layer IL7 may include PI. In an embodiment, the seventh insulating layer IL7 may be a first via layer.

A sixth layer 111 may be disposed on the seventh insulating layer IL7. The sixth layer 111 may be a conductive layer including metal. For example, the sixth layer 111 may include one or more selected from among Al, Pt, Pd, Ag, Mg, Au, Ni, Nd, Ir, Cr, Ca, Mo, Ti, W, and Cu. The sixth layer 111 may have a single layer or multiple layers. In an embodiment, the sixth layer 111 may include Al and Ti. In an embodiment, the sixth layer 111 may include a multi-layered structure in which Ti, Al, and Ti are sequentially arranged. In an embodiment, the sixth layer 111 may include a contact metal connecting the sixth drain electrode DE6 to the sub-pixel electrode 210 of the light-emitting diode LED.

An eighth insulating layer IL8 may be disposed on the sixth layer 111. The eighth insulating layer IL8 may entirely cover the sixth layer 111. The eighth insulating layer IL8 may include an organic insulating material. For example, the eighth insulating layer IL8 may include at least one selected from among benzocyclobutene, PI, hexamethyldisiloxane, a general commercial polymer such as polymethylmethacrylate or polystyrene, a polymer derivative having a phenol group, an acrylic polymer, an imide polymer, an aryl ether polymer, an amide polymer, a fluorine polymer, a p-xylene polymer, a vinyl alcohol polymer, or the like. The eighth insulating layer IL8 may have a single layer or multiple layers. In an embodiment, the eighth insulating layer IL8 may include PI. In an embodiment, the eighth insulating layer IL8 may be a second via layer. In an embodiment, the seventh insulating layer IL7 and the eighth insulating layer IL8 may include the same material.

The light-emitting diode LED may be disposed on the eighth insulating layer IL8. The light-emitting diode LED may include the sub-pixel electrode 210, an intermediate layer 220, and the opposite electrode 230.

The sub-pixel electrode 210 may be disposed on the eighth insulating layer IL8. The sub-pixel electrode 210 may include at least one conductive oxide selected from among indium tin oxide (ITO), indium zinc oxide (IZO), zinc oxide (ZnO), indium oxide (In₂O₃) indium gallium oxide (IGO), and aluminum zinc oxide (AZO). When the sub-pixel electrode 210 is formed as a reflective electrode, the sub-pixel electrode 210 may include a reflective film, the reflective film including at least one selected from among Ag, Mg, Al, Pt, Pd, Au, Ni, Nd, Ir, Cr, and compounds thereof. In an embodiment, the sub-pixel electrode 210 may include ITO and Ag. In an embodiment, the sub-pixel electrode 210 may include a multi-layered structure in which ITO, Ag, and ITO are sequentially arranged.

A ninth insulating layer IL9 may be disposed on the sub-pixel electrode 210. The ninth insulating layer IL9 may cover the edge area of the sub-pixel electrode 210. In other words, the ninth insulating layer IL9 may include an opening overlapping the central portion of the sub-pixel electrode 210. The opening of the ninth insulating layer IL9 may define an emission area of the light-emitting diode LED and may also define an emission area of a sub-pixel. In an embodiment, the ninth insulating layer IL9 may be a pixel defining layer.

The intermediate layer 220 may be disposed on the sub-pixel electrode 210. The intermediate layer 220 may include a first functional layer 221 and a second functional layer 223, which are disposed above the ninth insulating layer IL9, and an emission layer 222 arranged within the opening of the ninth insulating layer IL9. In an embodiment, the first functional layer 221 may be disposed on the ninth insulating layer IL9, the emission layer 222 may be disposed on the first functional layer 221 and may be arranged within the opening of the ninth insulating layer IL9, and the second functional layer 223 may be disposed above the first functional layer 221 to cover the emission layer 222. In other words, the emission layer 222 may be arranged within the opening of the ninth insulating layer IL9, and may be arranged between the first functional layer 221 and the second functional layer 223.

The emission layer 222 may include an organic emission layer including a low-molecular-weight material or a polymer material. The first functional layer 221 may include an electron transport layer (ETL) and/or an electron injection layer (EIL). The second functional layer 223 may include a hole transport layer (HTL) and/or a hole injection layer (HIL). In an embodiment, the first functional layer 221 or the second functional layer 223 may be omitted. In an embodiment, the positions of the first functional layer 221 and the second functional layer 223 may be interchanged.

The opposite electrode 230 may be disposed on the intermediate layer 220. For example, the opposite electrode 230 may be disposed on the second functional layer 223. The opposite electrode 230 may be arranged to entirely cover the intermediate layer 220. The opposite electrode 230 may include a conductive material having a low work function. For example, the opposite electrode 230 may include at least one selected from among Ag, Mg, Al, Pt, Pd, Au, Ni, Nd, Ir, Cr, Li, Ca, alloys thereof, or the like. The opposite electrode 230 may have a single layer or may include a multi-layered structure.

An encapsulation layer 300 may be disposed on the light-emitting diode LED. The encapsulation layer 300 may entirely cover the light-emitting diode LED. The encapsulation layer 300 may include at least one inorganic encapsulation layer and at least one organic encapsulation layer 320. For example, the encapsulation layer 300 may include a first inorganic encapsulation layer 310, a second inorganic encapsulation layer 330, and the organic encapsulation layer 320. The organic encapsulation layer 320 may be arranged between the first inorganic encapsulation layer 310 and the second inorganic encapsulation layer 330. Each of the first inorganic encapsulation layer 310 and the second inorganic encapsulation layer 330 may include an inorganic insulating material. For example, the first inorganic encapsulation layer 310 and/or the second inorganic encapsulation layer 330 may include at least one selected from among silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO). The organic encapsulation layer 320 may include an organic insulating material. For example, the organic encapsulation layer 320 may include a polymer-based material. The polymer-based material may include a silicone-based resin, an acryl-based resin, an epoxy-based resin, PI, polyethylene, or the like.

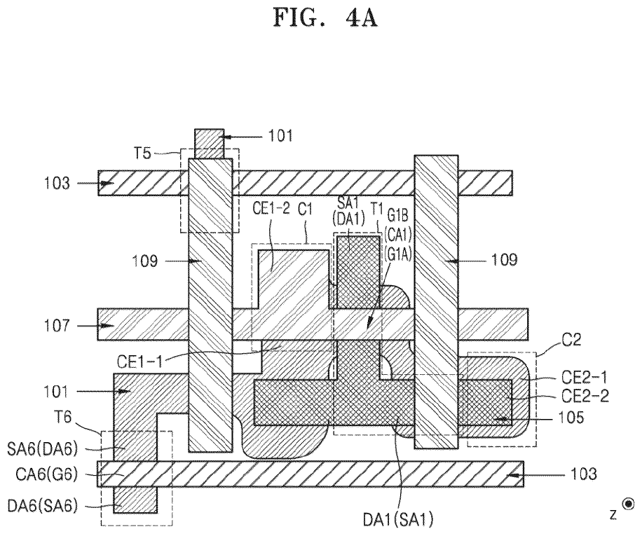

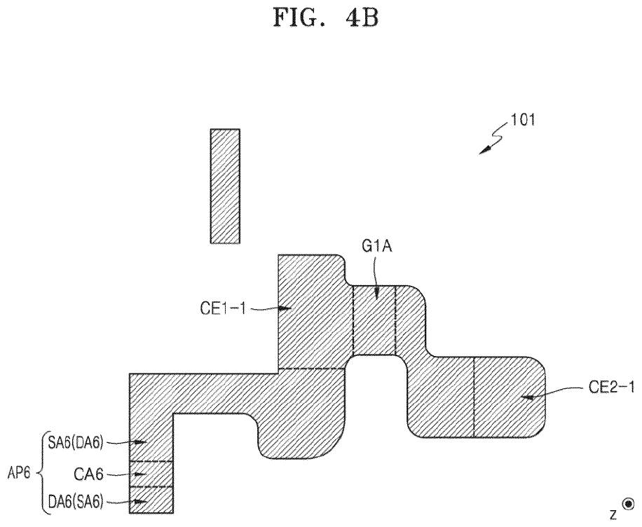

FIGS. 4A and 4B are schematic plan views each illustrating a portion of a display apparatus according to an embodiment. FIG. 4B is a plan view showing an excerpt of some layers (e.g., the first layer 101) in FIG. 4A.

Referring to FIGS. 4A and 4B, the first layer 101, the second layer 103, the third layer 105, the fourth layer 107, and the fifth layer 109 may be arranged to form the first transistor T1, the sixth transistor T6, the first capacitor C1 and the second capacitor C2. For convenience of illustration and explanation, insulating layers arranged between the layers are omitted. The first layer 101, the second layer 103, the third layer 105, the fourth layer 107, and the fifth layer 109 may be sequentially arranged in one direction (e.g., a z direction).

The first layer 101 and the second layer 103 may overlap each other in an area included in the sixth transistor T6. A portion of the first layer 101 which overlaps the second layer 103 may be the sixth channel area CA6 of the sixth active pattern AP6 (refer to FIG. 4B). A portion of the second layer 103 which overlaps the first layer 101 may be the sixth gate electrode G6. The sixth source area SA6 may be disposed on one side of the sixth channel area CA6. The sixth drain area DA6 may be disposed on another side of the sixth channel area CA6. In an embodiment, positions of the sixth source area SA6 and the sixth drain area DA6 may be interchangeable.

In an embodiment, a portion of an area where the first layer 101, the second layer 103, and the fifth layer 109 overlap each other may be included in the fifth transistor T5.

The first layer 101, the third layer 105, and the fourth layer 107 may overlap each other in an area included in the first transistor T1. A portion of the first layer 101 which overlaps the third layer 105 and/or the fifth layer 109 may be the first lower gate electrode GIA (refer to FIG. 4B). A portion of the fifth layer 109 which overlaps the first layer 101 and/or the third layer 105 may be the first upper gate electrode G1B. A portion of the third layer 105 which overlaps the first layer 101 and/or the fifth layer 109 may be the first channel area CA1. The first source area SA1 may be disposed on one side of the first channel area CA1. The first drain area DA1 may be disposed on another side of the first channel area CA1. In an embodiment, the first source area SA1 and the first drain area DA1 may be interchangeable.

The first layer 101 and the fourth layer 107 may overlap each other in an area included in the first capacitor C1. A portion of the first layer 101 which overlaps the fourth layer 107 may be the first-1 electrode CE1-1 (refer to FIG. 4B). A portion of the fourth layer 107 which overlaps the first layer 101 may be the first-2 electrode CE1-2.

The first layer 101 and the third layer 105 may overlap each other in an area included in the second capacitor C2. A portion of the first layer 101 which overlaps the third layer 105 may be the second-1 electrode CE2-1 (refer to FIG. 4B). A portion of the third layer 105 which overlaps the first layer 101 may be the second-2 electrode CE2-2.

Referring to FIG. 4B, the first lower gate electrode GIA, the sixth active pattern AP6, the first-1 electrode CE1-1, and the second-1 electrode CE2-1 may be connected to each other to form a single body in the first layer 101. In an embodiment, each of the first lower gate electrode GIA, the first-1 electrode CE1-1, the second-1 electrode CE2-1, the sixth source area SA6, and the sixth drain area DA6 may include a doped (e.g., P-doped) polysilicon semiconductor. In an embodiment, the sixth channel area CA6 may include an undoped polysilicon semiconductor.

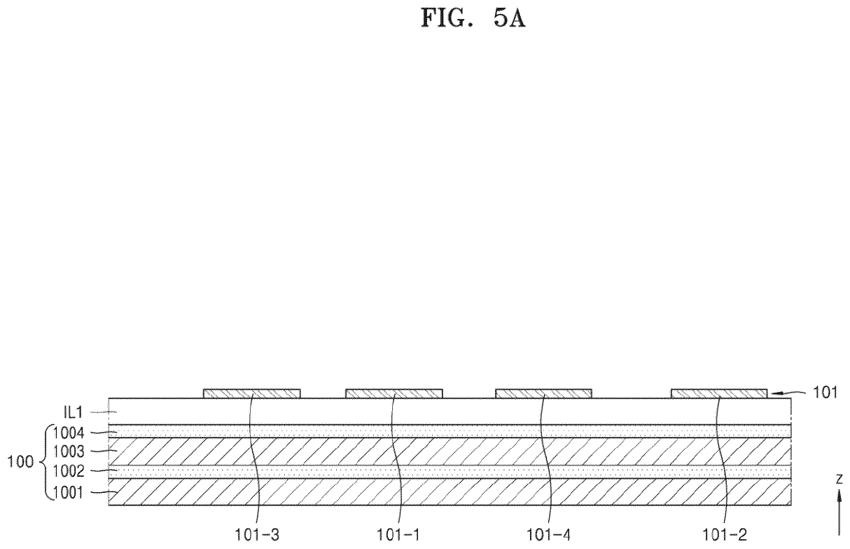

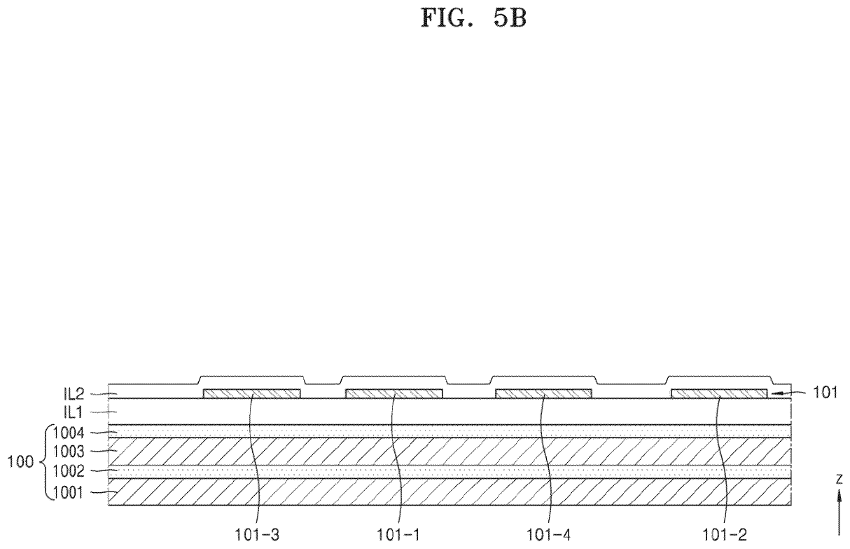

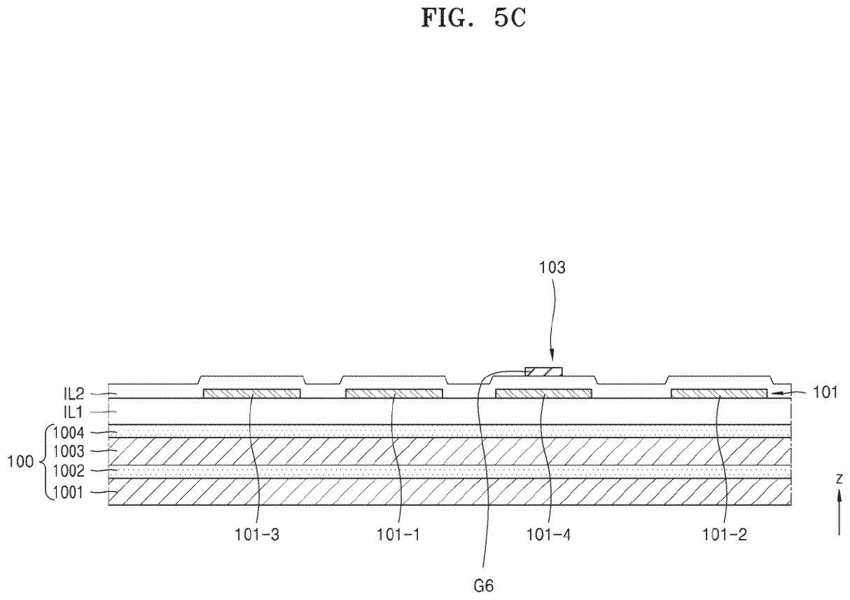

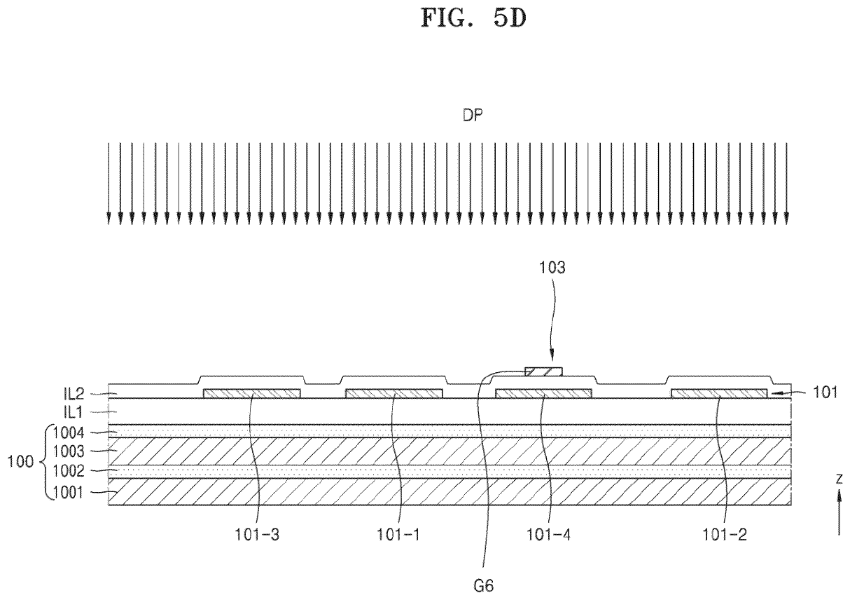

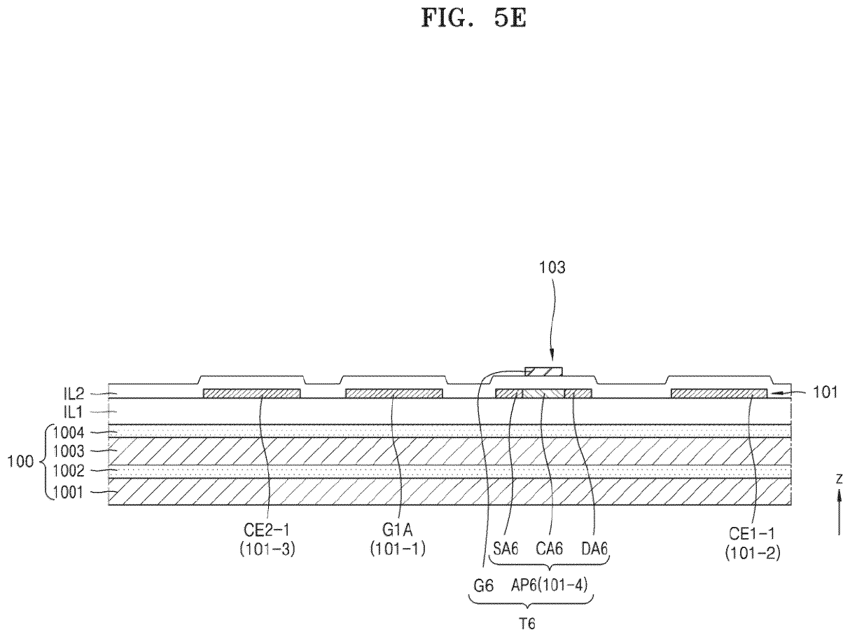

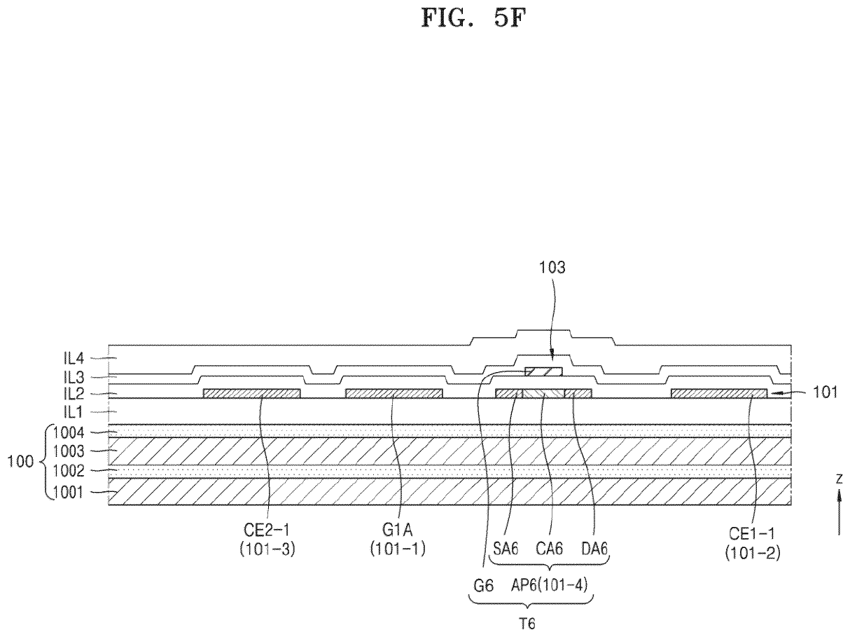

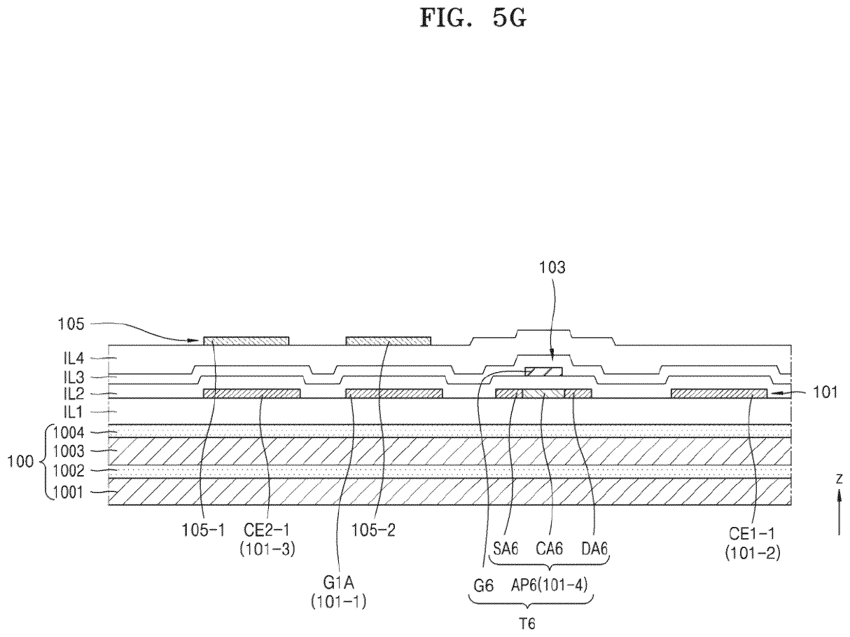

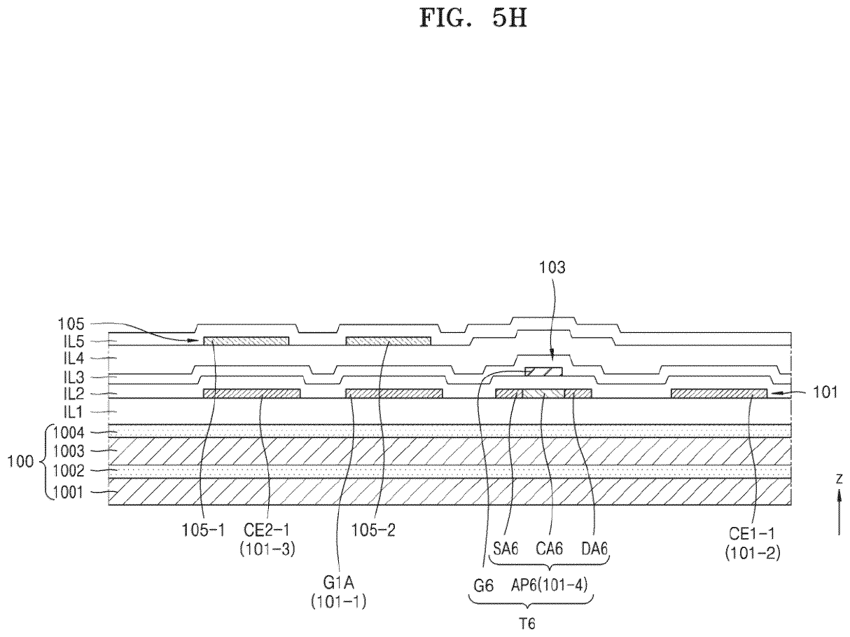

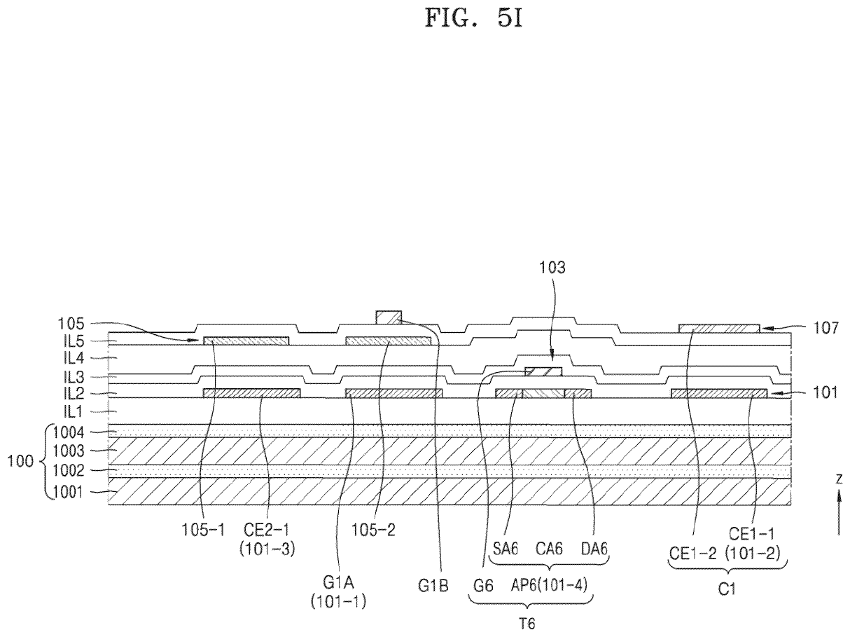

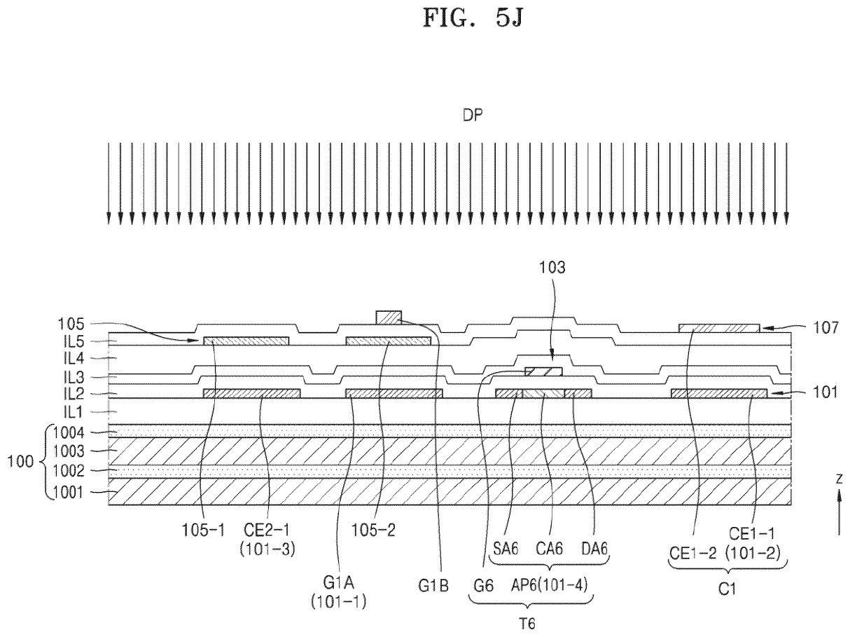

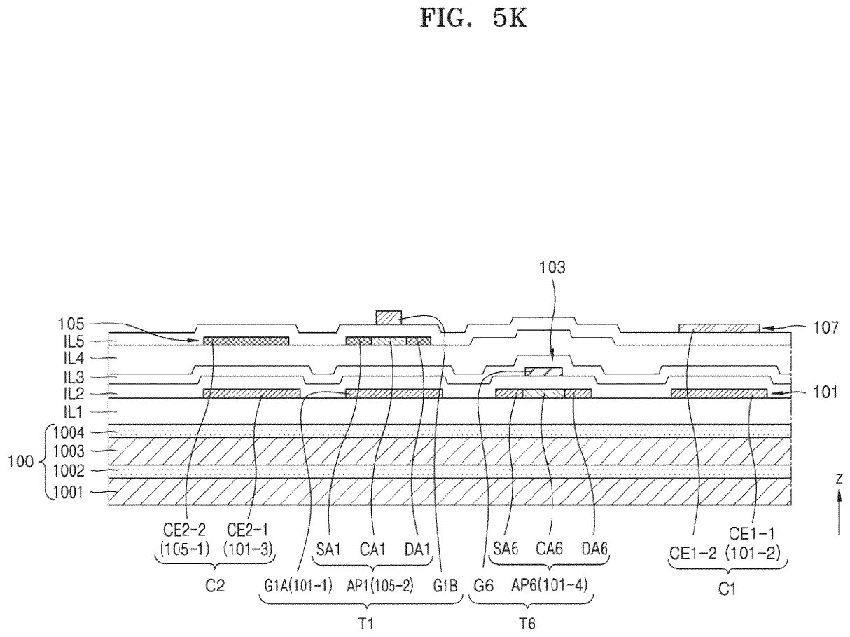

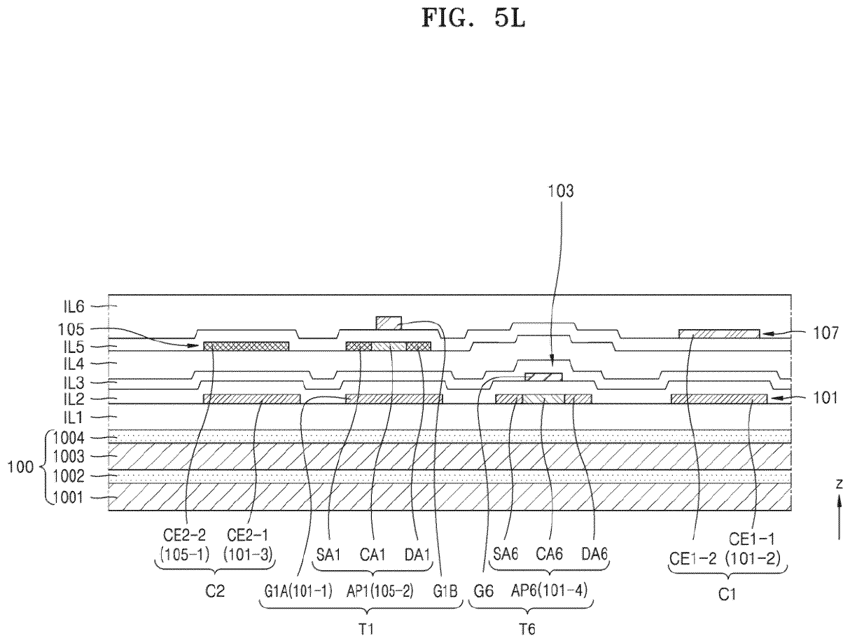

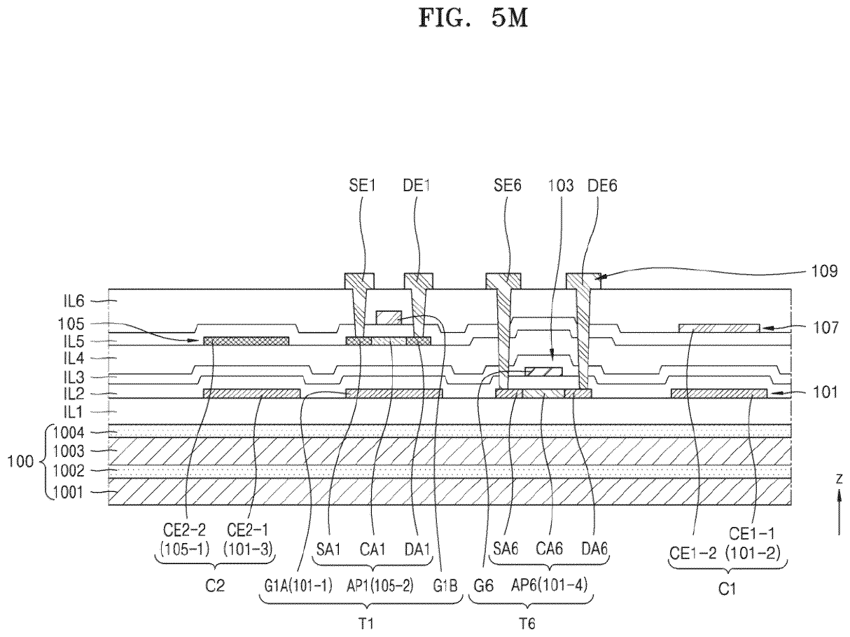

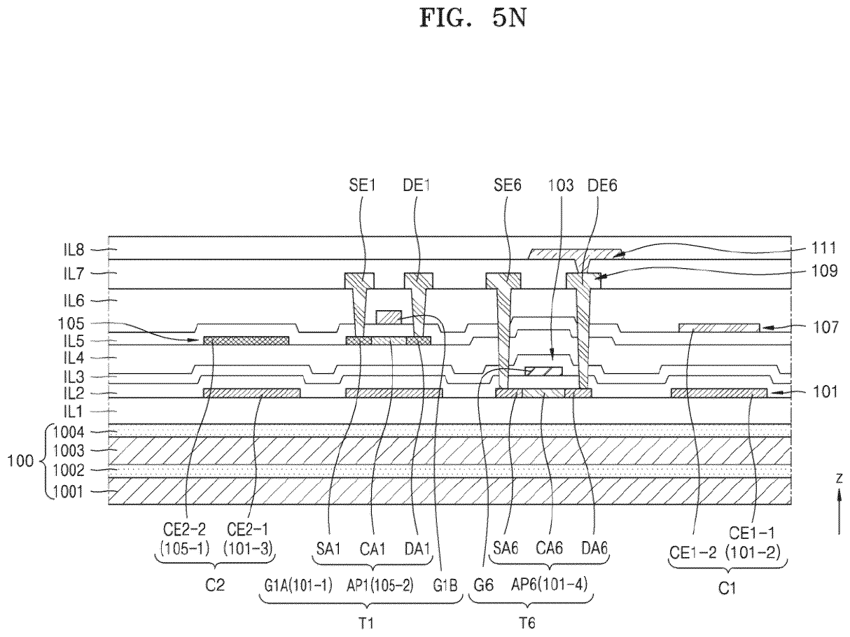

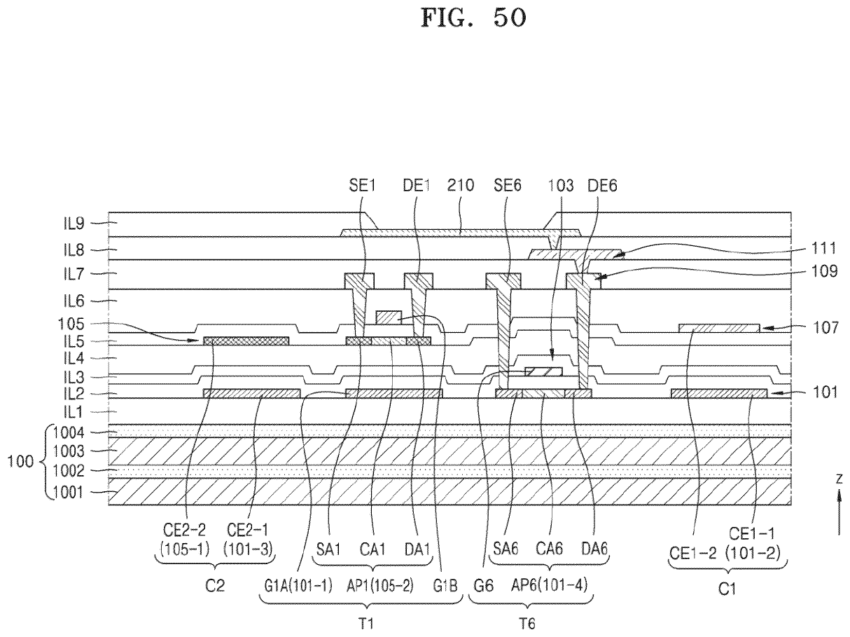

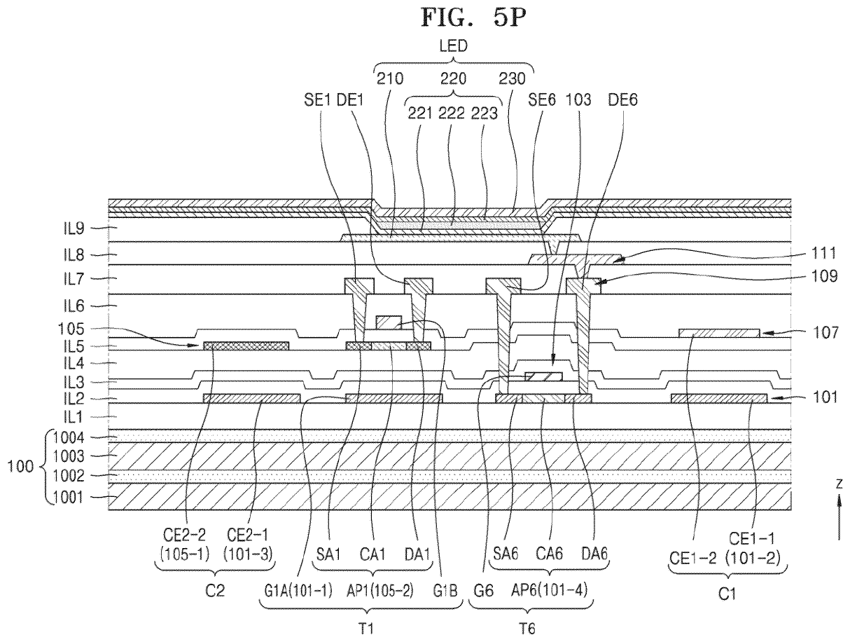

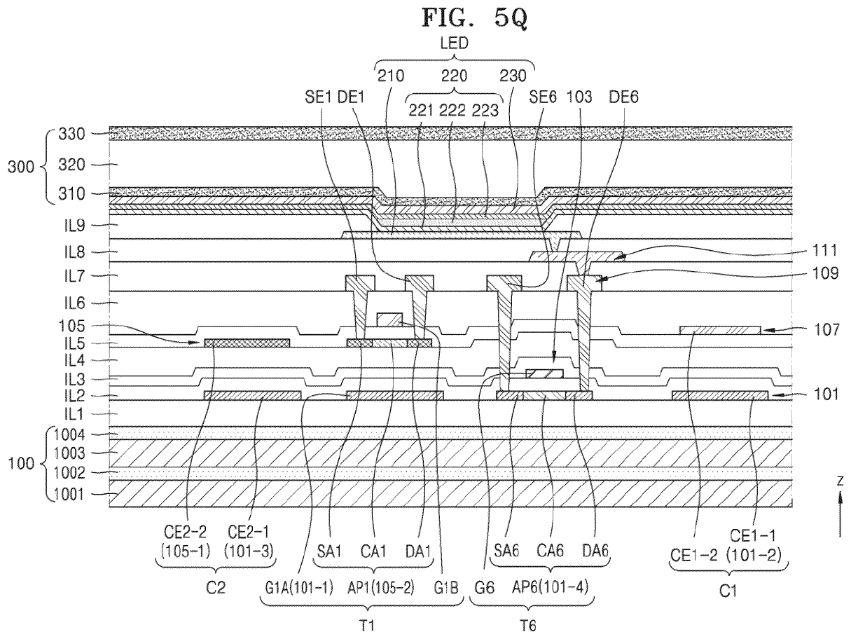

FIGS. 5A to 5Q are cross-sectional views showing a method of manufacturing a display apparatus according to an embodiment.

Referring to FIG. 5A, the first insulating layer IL1 may be formed on the substrate 100, and a first semiconductor pattern 101 may be formed on the first insulating layer IL1. The first semiconductor pattern 101 may correspond to the first layer 101 described above with reference to FIG. 3. The first semiconductor pattern 101 may include a first portion 101-1, a second portion 101-2, a third portion 101-3, and a fourth portion 101-4. In an embodiment, the shape of the first semiconductor pattern 101 may be entirely similar to the shape of the first layer 101 described above with reference to FIGS. 4A and 4B. That is, in the following cross-sectional views, the first portion 101-1, the second portion 101-2, the third portion 101-3, and the fourth portion 101-4 of the first semiconductor pattern 101 are shown as being spaced apart from each other, but the first portion 101-1, the second portion 101-2, the third portion 101-3, and the fourth portion 101-4 of the first semiconductor pattern 101 may be connected to each other to form a single body as shown in FIGS. 4A and 3B. The first semiconductor pattern 101 may include a low-temperature polycrystalline silicon semiconductor (e.g., LTPS). At this process of the method, the first semiconductor pattern 101 may be in an undoped state.

Referring to FIG. 5B, the second insulating layer IL2 may be formed on the first semiconductor pattern 101. The second insulating layer IL2 may entirely cover the first semiconductor pattern 101. At this process of the method, the first semiconductor pattern 101 may be in an undoped state.

Referring to FIG. 3, the second layer 103 may be formed on the second insulating layer IL2. The sixth gate electrode G6 may be formed above the fourth portion 101-4 of the first semiconductor pattern 101. The sixth gate electrode G6 may overlap a portion of the fourth portion 101-4 of the first semiconductor pattern 101. At this process of the method, the first semiconductor pattern 101 may be in an undoped state.

Referring to FIG. 5D, the structure described above may be doped. In other words, a dopant DP may be irradiated toward the entire above structure. For example, the dopant DP may be irradiated toward the first semiconductor pattern 101. In an embodiment, the first semiconductor pattern 101 may include a low-temperature polycrystalline silicon semiconductor (e.g., LTPS), and the dopant DP may include boron (B). In this case, the doping may be P-doping. In another embodiment, the dopant DP may be irradiated only to an area overlapping the first semiconductor pattern 101 instead of being irradiated to the entire surface of the structure.

Referring to FIGS. 5D and 5E, a portion of the dopant DP irradiated toward the first semiconductor pattern 101 may reach the first semiconductor pattern 101 via the second insulating layer IL2. For example, a portion of the dopant DP may reach the first portion 101-1, the second portion 101-2, and the third portion 101-3 of the first semiconductor pattern 101 via the second insulating layer IL2. Accordingly, the first portion 101-1, the second portion 101-2, and the third portion 101-3 may be doped (e.g., P-doped). The dopant DP may reach a portion of the fourth portion 101-4 of the first semiconductor pattern 101 which does not overlap the sixth gate electrode G6. Accordingly, the portion of the fourth portion 101-4 which does not overlap with the sixth gate electrode G6 may be doped (e.g., P-doped). The dopant DP may not pass through the sixth gate electrode G6. Accordingly, the dopant DP may not reach a portion of the fourth portion 101-4 of the first semiconductor pattern 101 which overlaps the sixth gate electrode G6. Accordingly, the portion of the fourth portion 101-4 which overlaps the sixth gate electrode G6, may remain in the undoped state. In an embodiment, the sixth gate electrode G6 may function as a self-aligned mask, for example, a blocking mask.

The first portion 101-1 of the first semiconductor pattern 101 which is doped may correspond to the first lower gate electrode GIA. In other words, the first lower gate electrode GIA may be formed by doping the first portion 101-1 of the first semiconductor pattern 101.

The second portion 101-2 of the first semiconductor pattern 101 which is doped may correspond to the first-1 electrode CE1-1. In other words, the first-1 electrode CE1-1 may be formed by doping the second portion 101-2 of the first semiconductor pattern 101.

The third portion 101-3 of the first semiconductor pattern 101 which is doped may correspond to the second-1 electrode CE2-1. In other words, the second-1 electrode CE2-1 may be formed by doping the third portion 101-3 of the first semiconductor pattern 101.

The fourth portion 101-4 of the first semiconductor pattern 101 may correspond to the sixth active pattern AP6. In other words, the sixth active pattern AP6 may be formed by doping (partially) the fourth portion 101-4 of the first semiconductor pattern 101. The doped portions of the fourth portion 101-4 of the first semiconductor pattern 101 may be the sixth source area SA6 and the sixth drain area DA6 of the sixth active pattern AP6. The undoped portion of the fourth portion 101-4 of the first semiconductor pattern 101 may be the sixth channel area CA6.

In an embodiment, the sixth source area SA6, the sixth drain area DA6, the first lower gate electrode GIA, the first-1 electrode CE1-1, and the second-1 electrode CE2-1 may be formed substantially at the same time.

Referring to FIG. 5F, the third insulating layer IL3 and the fourth insulating layer IL4 may be sequentially formed on the second layer 103. The third insulating layer IL3 may cover the second layer 103 (e.g., the sixth gate electrode G6). The fourth insulating layer IL4 may cover the third insulating layer IL3.

Referring to FIG. 5G, a second semiconductor pattern 105 may be formed on the fourth insulating layer IL4. The second semiconductor pattern 105 may correspond to the third layer 105 described above with reference to FIG. 3. The second semiconductor pattern 105 may include a first portion 105-1 and a second portion 105-2. The first portion 105-1 of the second semiconductor pattern 105 may overlap the third portion 101-3 of the first semiconductor pattern 101. The second portion 105-2 of the second semiconductor pattern 105 may overlap the first portion 101-1 of the first semiconductor pattern 101. In an embodiment, the shape of the second semiconductor pattern 105 may be entirely similar to the shape of the third layer 105 described above with reference to FIG. 4A. That is, in the following cross-sectional views, the first portion 105-1 and the second portion 105-2 of the second semiconductor pattern 105 are shown as being spaced apart from each other, but the first portion 105-1 and the second portion 105-2 of the second semiconductor pattern 105 may be connected to each other to form a single body as shown in FIG. 4A. The second semiconductor pattern 105 may include an oxide semiconductor (e.g., IGZO). At this process of the method, the second semiconductor pattern 105 may be in an undoped state.

Referring to FIG. 5H, the fifth insulating layer IL5 may be disposed on the second semiconductor pattern 105. The fifth insulating layer IL5 may entirely cover the second semiconductor pattern 105. At this process of the method, the second semiconductor pattern 105 may be in an undoped state.

Referring to FIG. 5I, the fourth layer 107 may be formed on the fifth insulating layer IL5. The first upper gate electrode GIB may be formed on the second portion 105-2 of the second semiconductor pattern 105. The first upper gate electrode G1B may overlap a portion of the second portion 105-2 of the second semiconductor pattern 105. The first-2 electrode CE1-2 may be formed on the second portion 101-2 of the first semiconductor pattern 101 (or the first-1 electrode CE1-1). The first-1 electrode CE1-1 and the first-2 electrode CE1-2 may overlap each other and may form the first capacitor C1. At this process of the method, the second semiconductor pattern 105 may be in an undoped state.

Referring to FIG. 5J, the structure described above may be doped. In other words, the dopant DP may be irradiated toward the entire above structure. For example, the dopant DP may be irradiated toward the second semiconductor pattern 105. In an embodiment, the second semiconductor pattern 105 may include an oxide semiconductor (e.g., IGZO), and the dopant DP may include B. In this case, the doping may be N-doping. In another embodiment, the dopant DP may be irradiated only to an area overlapping the second semiconductor pattern 105 instead of being irradiated toward the entire surface of the structure.

Referring to FIGS. 5J and 5K, a portion of the dopant DP irradiated toward the second semiconductor pattern 105 may reach the second semiconductor pattern 105 via the fifth insulating layer IL5. For example, a portion of the dopant DP may reach the first portion 105-1 of the second semiconductor pattern 105 via the fifth insulating layer IL5. Accordingly, the first portion 105-1 of the second semiconductor pattern 105 may be doped (e.g., N-doped). The dopant DP may reach a portion of the second portion 105-2 of the second semiconductor pattern 105 which does not overlap the first upper gate electrode G1B. Accordingly, the portion of the second portion 105-2 which does not overlap with the first upper gate electrode G1B may be doped (e.g., N-doped). The dopant DP may not pass through the first upper gate electrode G1B. Accordingly, the dopant DP may not reach the portion of the second portion 105-2 of the second semiconductor pattern 105 which overlaps the first upper gate electrode G1B. Accordingly, the portion of the second portion 105-2 which overlaps the first upper gate electrode GIB may remain in the undoped state. In an embodiment, the first upper gate electrode G1B may function as a self-aligned mask, for example a blocking mask.

The first portion 105-1 of the second semiconductor pattern 105 which is doped may correspond to the second-2 electrode CE2-2. In other words, the second-2 electrode CE2-2 may be formed by doping the first portion 105-1 of the second semiconductor pattern 105. The second-1 electrode CE2-1 and the second-2 electrode CE2-2 may overlap each other to form the second capacitor C2.

The second portion 105-2 of the second semiconductor pattern 105 may correspond to the first active pattern AP1. In other words, the first active pattern AP1 may be formed by doping (partially) the second portion 105-2 of the second semiconductor pattern 105. The doped portions of the second portion 105-2 of the second semiconductor pattern 105 may be the first source area SA1 and the first drain area DA1 of the first active pattern AP1. The undoped portion of the second portion 105-2 of the second semiconductor pattern 105 may be the first channel area CA1.

In an embodiment, the first source area SA1, the first drain area DA1, and the second-2 electrode CE2-2 may be formed substantially at the same time.

Referring to FIG. 5L, the sixth insulating layer IL6 may be formed on the fourth layer 107. The sixth insulating layer IL6 may cover the fourth layer 107 (e.g., the first upper gate electrode G1B and the first-2 electrode CE1-2).

Referring to FIG. 5M, the fifth layer 109 may be formed on the sixth insulating layer IL6. A plurality of contact holes may be arranged in the sixth insulating layer IL6, and a plurality of electrodes may be formed on the sixth insulating layer IL6. For example, contact holes respectively exposing the first source area SA1, the first drain area DA1, the sixth source area SA6, and the sixth drain area DA6 may be formed. The first source electrode SE1 may be formed on the sixth insulating layer IL6 to overlap the first source area SA1, and may be connected to the first source area SA1 through the contact hole. The first drain electrode DE1 may be disposed on the sixth insulating layer IL6 to overlap the first drain area DA1, and may be connected to the first drain area DA1 through the contact hole. The sixth source electrode SE6 may be disposed on the sixth insulating layer IL6 to overlap the sixth source area SA6, and may be connected to the sixth source area SA6 through the contact hole. The sixth drain electrode DE6 may be disposed on the sixth insulating layer IL6 to overlap the sixth drain area DA6, and may be connected to the sixth drain area DA6 through the contact hole.

Referring to FIG. 5N, the seventh insulating layer IL7, the sixth layer 111, and the eighth insulating layer IL8 may be sequentially formed on the fifth layer 109. The contact metal of the sixth layer 111 may be connected to the fifth layer 109 (e.g., the sixth drain electrode DE6) through a contact hole formed in the seventh insulating layer IL7.

Referring to FIG. 5O, the sub-pixel electrode 210 and the ninth insulating layer IL9 may be formed on the eighth insulating layer IL8. The sub-pixel electrode 210 may be connected to the sixth layer 111 (e.g., the contact metal) through a contact hole formed in the eighth insulating layer IL8. The sub-pixel electrode 210 may be connected to the sixth drain area DA6 and further to the sixth transistor T6 through the sixth layer 111 and the fifth layer 109. For example, the sub-pixel electrode 210 may be connected to the sixth drain area DA6 and further to the sixth transistor T6 through the contact metal of the sixth layer 111 and the sixth drain electrode DE6 of the fifth layer 109. An opening may be defined in the ninth insulating layer IL9 to expose the central portion of the sub-pixel electrode 210.

Referring to FIG. 5P, the intermediate layer 220 and the opposite electrode 230 may be sequentially formed on the sub-pixel electrode 210 and the ninth insulating layer IL9. The intermediate layer 220 may include the first functional layer 221, the emission layer 222, and the second functional layer 223. The emission layer 222 may be arranged between the first function layer 221 and the second functional layer 223. The sub-pixel electrode 210, the intermediate layer 220, and the opposite electrode 230 may overlap each other and may form the light-emitting diode LED.

Referring to FIG. 5Q, the encapsulation layer 300 may be formed on the light-emitting diode LED. The encapsulation layer 300 may include the first inorganic encapsulation layer 310, the organic encapsulation layer 320, and the second inorganic encapsulation layer 330. The organic encapsulation layer 320 may be arranged between the first inorganic encapsulation layer 310 and the second inorganic encapsulation layer 330.

According to an embodiment described above, electrodes may be formed on the same layer as an active pattern of a first transistor including a silicon semiconductor. For example, electrodes of several capacitors may be formed on the same layer as the active pattern of the first transistor. For example, a lower gate electrode of a second transistor including an oxide semiconductor may be formed on the same layer as the active pattern of the first transistor.

As an effect of the disclosure, a threshold voltage (Vth) of the second transistor including an oxide semiconductor of a display apparatus may be adjusted. Accordingly, the display apparatus with improved quality may be implemented.

As an effect of the disclosure, the number of masks required in a method of manufacturing a display apparatus may be reduced. Accordingly, the manufacturing cost of a display apparatus may be reduced.

The scope of the disclosure is not limited to the above effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a first transistor disposed on the substrate and comprising a first active pattern comprising a polysilicon semiconductor; and
a second transistor disposed on the substrate and comprising a second active pattern and a lower gate electrode insulated from the second active pattern and disposed below the second active pattern, the second active pattern comprising an oxide semiconductor,
wherein the lower gate electrode of the second transistor comprises a same material and is disposed on a same plane as the first active pattern of the first transistor.

2. The display apparatus of claim 1, wherein the lower gate electrode and the first active pattern are connected to each other to form a single body.

3. The display apparatus of claim 1, wherein the lower gate electrode comprises a doped polysilicon semiconductor.

4. The display apparatus of claim 1, further comprising a first capacitor comprising a first-1 electrode and a first-2 electrode,
wherein the first-1 electrode comprises the same material and is disposed on the same plane as the first active pattern.

5. The display apparatus of claim 4, wherein the second transistor further comprises an upper gate electrode insulated from the second active pattern and disposed on the second active pattern, and
wherein the upper gate electrode of the second transistor and the first-2 electrode of the first capacitor comprise a same material and are disposed on a same plane.

6. The display apparatus of claim 4, further comprising a second capacitor comprising a second-1 electrode and a second-2 electrode,
wherein the second-1 electrode comprises the same material and is disposed on the same plane as the first active pattern, and
wherein the second-2 electrode comprises a same material and is disposed on a same plane as the second active pattern.

7. The display apparatus of claim 6, wherein each of the first-1 electrode and the second-1 electrode comprises a doped polysilicon semiconductor.

8. The display apparatus of claim 6, wherein the second-2 electrode comprises a doped oxide semiconductor.

9. The display apparatus of claim 6, wherein the second-2 electrode and the second active pattern are connected to each other to form a single body.

10. The display apparatus of claim 6, wherein the first active pattern, the lower gate electrode, the first-1 electrode, and the second-1 electrode are connected to each other to form a single body.

11. A method of manufacturing a display apparatus, the method comprising:
forming a first semiconductor pattern comprising a polysilicon semiconductor on a substrate;
forming a lower gate electrode by doping a first portion of the first semiconductor pattern; and
forming a second semiconductor pattern comprising an oxide semiconductor on the lower gate electrode to be insulated from the lower gate electrode.

12. The method of claim 11, wherein a first-1 electrode of a first capacitor and a second-1 electrode of a second capacitor are formed at the same time when doping the first portion of the first semiconductor pattern by doping a second portion of the first semiconductor pattern and a third portion of the first semiconductor pattern, respectively.

13. The method of claim 12, wherein the forming of the lower gate electrode, the forming of the first-1 electrode, and the forming of the second-1 electrode are substantially performed simultaneously.

14. The method of claim 12, further comprising:
forming a first gate electrode on a fourth portion of the first semiconductor pattern; and
doping the first semiconductor pattern comprising the first portion, the second portion, the third portion, and the fourth portion.

15. The method of claim 14, further comprising forming a first source electrode and a first drain electrode on the first semiconductor pattern to be connected to the fourth portion of the first semiconductor pattern.

16. The method of claim 12, further comprising:
forming a first-2 electrode insulated from the first-1 electrode on the first-1 electrode of the first capacitor and an upper gate electrode on the second semiconductor pattern to be insulated from the second semiconductor pattern,
wherein the forming of the upper gate electrode and the forming of the first-2 electrode are substantially performed simultaneously.

17. The method of claim 16, further comprising forming a second-2 electrode of the second capacitor by doping a first portion of the second semiconductor pattern.

18. The method of claim 17, wherein the forming of the upper gate electrode comprises forming the upper gate electrode on a second portion of the second semiconductor pattern, and
wherein the forming of the second-2 electrode comprises doping the second semiconductor pattern comprising the first portion and the second portion.

19. The method of claim 18, further comprising forming a second source electrode and a second drain electrode on the second semiconductor pattern to be connected to the second portion of the second semiconductor pattern.

20. An electronic device comprising a display apparatus, wherein the display apparatus comprises:
a substrate;
a first transistor disposed on the substrate and comprising a first active pattern comprising a polysilicon semiconductor; and
a second transistor disposed on the substrate and comprising a second active pattern and a lower gate electrode insulated from the second active pattern and disposed below the second active pattern, the second active pattern comprising an oxide semiconductor,
wherein the lower gate electrode of the second transistor comprises a same material and is formed on a same plane as the first active pattern of the first transistor.
